(19) United States
(12) Patent Application Publication
(10) Pub. No.: US 2025/0020995 A1
(43) Pub. Date: Jan. 16, 2025

(54) PHOTOSENSITIVE RESIN COMPOSITION, PHOTOSENSITIVE RESIN LAYER USING THE SAME, DISPLAY DEVICE AND MANUFACTURING METHOD OF PHOTOSENSITIVE RESIN LAYER

(71) Applicant: SAMSUNG SDI CO., LTD., Yongin-si (KR)

(72) Inventors: Seungbeom KEE, suwon-s Gyeonggi- (KR); Juho JUNG, Suwon-si (KR); Baek Soung PARK, Suwon-si (KR); Jieun KIM, Suwon-si (KR); Donghyun PARK, Suwon-si (KR); Jihong KIM, Suwon-si (KR)

(21) Appl. No.: 18/756,197

(22) Filed: Jun. 27, 2024

(30) Foreign Application Priority Data
Jul. 7, 2023 (KR) 10-2023-0088564
May 21, 2024 (KR) 10-2024-0065960

(51) Int. Cl. G03F 7/00; G03F 7/033; G03F 7/38; H10K 59/12; H10K 59/38; H10K 71/40; H10K 85/10

(52) U.S. Cl. CPC G03F 7/0007; G03F 7/033; G03F 7/38; H10K 59/1201; H10K 59/38; H10K 71/40; H10K 85/141

(57) ABSTRACT

A photosensitive resin composition, a photosensitive resin layer manufactured using the photosensitive resin composition, a display device including the photosensitive resin layer, and a method of manufacturing the photosensitive resin layer, the photosensitive resin composition, includes a binder resin; a colorant; a polymerizable monomer; a polymerization initiator; and a solvent.

### CROSS-REFERENCE TO RELATED APPLICATION

This application claims priority to and the benefit of Korean Patent Application No. 10-2023-0088564 filed in the Korean Intellectual Property Office on Jul. 7, 2023, and Korean Patent Application No. 10-2024-0065960 filed in the Korean Intellectual Property Office on May 21, 2024, the entire contents of which are incorporated herein by reference.

### BACKGROUND

### 1. Field

Embodiments relate to a photosensitive resin composition, a photosensitive resin layer using the same, a display device, and a method of manufacturing the photosensitive resin layer.

### 2. Description of the Related Art

Recently, interest in self-emitting (emissive) micro OLED display panels, which may be applied to VR (Virtual Reality), AR (Augmented Reality), and MR (Mixed Reality) devices, is increasing.

### SUMMARY

The embodiments may be realized by providing a photosensitive resin composition including a binder resin; a colorant; a polymerizable monomer; a polymerization initiator; and a solvent wherein the binder resin includes at least one structural unit represented by Chemical Formula 1 or Chemical Formula 2, and at least two structural units represented by Chemical Formula 3 to Chemical Formula 5:

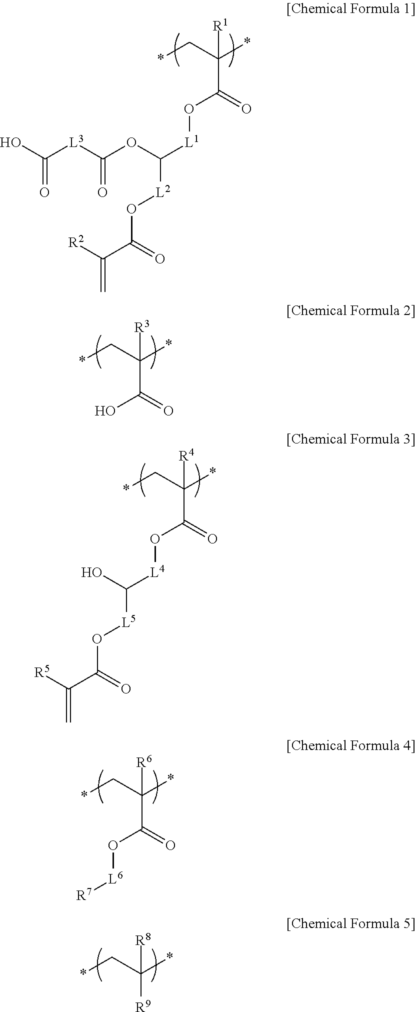

in Chemical Formula 1 to Chemical Formula 5, R¹ to R⁶ and R⁸ are each independently a hydrogen atom or a substituted or unsubstituted C1 to C20 alkyl group, R⁷ and R⁹ are each independently a substituted or unsubstituted C6 to C20 aryl group, and L¹ to L⁶ are each independently a single bond or a substituted or unsubstituted C1 to C20 alkylene group.

The binder resin may include a structural unit represented by Chemical Formula 1, a structural unit represented by Chemical Formula 3, a structural unit represented by Chemical Formula 4, and a structural unit represented by Chemical Formula 5.

In Chemical Formula 1 and Chemical Formula 3 to Chemical Formula 5, R¹, R⁴, and R⁶ may each independently be a substituted or unsubstituted C1 to C20 alkyl group, R², R⁵, and R¹ may each be a hydrogen atom, and L¹ to L⁶ may each independently be a substituted or unsubstituted C1 to C20 alkylene group.

The binder resin may have a weight average molecular weight of about 5,000 g/mol to about 8,000 g/mol.

The binder resin may have a double bond equivalent weight of about 150 g/mol to about 500 g/mol.

The photosensitive resin composition may include solids in an amount of about 12 wt % to about 24 wt %, based on a total weight of the photosensitive resin composition.

The polymerizable monomer may include a compound that includes three or more functional groups.

The polymerizable monomer may be a mixture of two types of compounds, and each compound of the two types of compounds may independently include three or more functional groups.

The two types of compounds may include a first polymerizable monomer including 3 to 5 functional groups, and a second polymerizable monomer including 6 or more functional groups, and the first polymerizable monomer may be included in an amount that is less than an amount of the second polymerizable monomer.

The photosensitive resin composition may include, based on a total weight of the photosensitive resin composition, about 5 wt % to about 20 wt % of the binder resin; about 70 wt % to about 90 wt % of the colorant; about 1 wt % to about 10 wt % of the polymerizable monomer; about 0.1 wt % to about 5 wt % of the polymerization initiator; and the solvent.

The photosensitive resin composition may further include an antioxidant.

The antioxidant may be included in an amount of about 0.01 wt % to about 1 wt %, based on a total weight of the photosensitive resin composition.

The photosensitive resin composition may further include malonic acid, 3-amino-1,2-propanediol, a silane coupling agent, a leveling agent, a surfactant, or a combination thereof.

The embodiments may be realized by providing a photosensitive resin layer manufactured using the photosensitive resin composition according to an embodiment.

The embodiments may be realized by providing a display device including the photosensitive resin layer according to an embodiment.

The display device may be a micro OLED display device including an OLED substrate deposited on a silicon wafer and a color filter layer stacked on the OLED substrate and converting white light generated from the OLED substrate into a plurality of color lights, and the color filter layer may include a red color filter, a green color filter, and a blue color filter.

The embodiments may be realized by providing a method of manufacturing a photosensitive resin layer, the method including coating the photosensitive resin composition according to an embodiment; prebaking at a temperature of about 100° C. or lower after the coating; exposing to i-line after the prebaking, and developing.

### BRIEF DESCRIPTION OF THE DRAWINGS

Features will be apparent to those of skill in the art by describing in detail exemplary embodiments with reference to the attached drawings in which:

FIGS. 1 and 4 are optical microscope images of a photosensitive resin layer obtained by curing the photosensitive resin composition according to Example 1 at a low temperature.

FIGS. 2 and 5 are optical microscope images of a photosensitive resin layer obtained by curing the photosensitive resin composition according to Comparative Example 1 at a low temperature.

FIGS. 3 and 6 are optical microscope images of a photosensitive resin layer obtained by curing the photosensitive resin composition according to Comparative Example 2 at a low temperature.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. As used herein, the term “or” is not necessarily an exclusive term, e.g., “A or B” would include A, B, or A and B. As used herein, hydrogen substitution (-H) may include deuterium substitution (-D) or tritium substitution (-T). For example, any hydrogen in any compound described herein may be protium, deuterium, or tritium (e.g., based on natural or artificial substitution).

As used herein, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As used herein, when specific definition is not otherwise provided, “substituted” refers to replacement of at least one hydrogen of a compound by a substituent selected from a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

As used herein, when specific definition is not otherwise provided, “hetero” refers to inclusion of at least one heteroatom of N, O, S, and P, in the chemical formula.

As used herein, when specific definition is not otherwise provided, “(meth)acrylate” refers to both “acrylate” and “methacrylate”, and “(meth)acrylic acid” refers to “acrylic acid” and “methacrylic acid”.

As used herein, when a definition is not otherwise provided, the term “combination” refers to mixing or copolymerization. Additionally, “copolymerization” refers to block copolymerization to random copolymerization, and “copolymer” refers to block copolymerization to random copolymerization.

In the chemical formula of the present specification, unless a specific definition is otherwise provided, hydrogen is bonded at the position when a chemical bond is not drawn where supposed to be given.

As used herein, when a definition is not otherwise provided, “*” refers to a linking part between the same or different atoms, or chemical formulas.

A photosensitive resin composition according to some embodiments may include, e.g., (A) a binder resin; (B) a colorant; (C) a polymerizable monomer; (D) a polymerization initiator; and (E) a solvent. In an implementation, the binder resin may include, e.g., at least one structural unit represented by Chemical Formula 1 or Chemical Formula 2, and at least two structural units represented by Chemical Formula 3 to Chemical Formula 5.

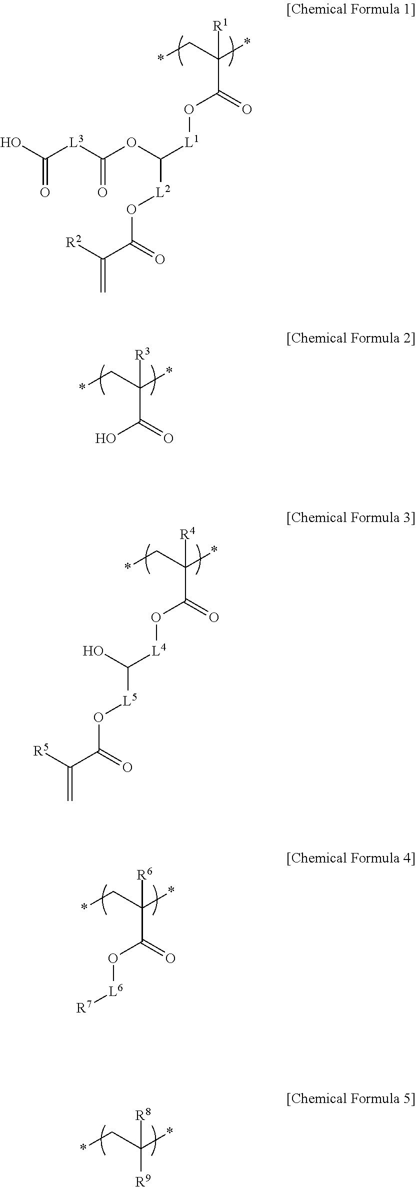

In Chemical Formula 1 to Chemical Formula 5, R¹ to R⁶ and R⁸ may each independently be or include, e.g., a hydrogen atom or a substituted or unsubstituted C1 to C20 alkyl group.

R⁷ and R⁹ may each independently be or include, e.g., a substituted or unsubstituted C6 to C20 aryl group.

L¹ to L⁵ may each independently be or include, e.g., a single bond or a substituted or unsubstituted C1 to C20 alkylene group.

Liquid crystal display devices, e.g., one type of display device, may have advantages of being lightweight, thin, low-cost, low-power, and highly compatible with integrated circuits and thus are more widely used for laptop computers, monitors, and TV images. Such liquid crystal display devices may have color filters in which a unit pixel including sub-pixels of red (R), green (G), and blue (B) corresponding to three primary colors of light is repeatedly formed. If each sub-pixel is adjacently placed, and color signals are applied to each sub-pixel to control brightness, the unit pixel displays a specific color by synthesizing three primary colors. The color filters may be made of red (R), green (G), and blue (B) dyes or pigments, and these color materials may change white light of a backlight unit into each corresponding color. The narrower absorption band in the spectra of these color materials have a without unnecessary wavelengths other than the required absorption wavelength, the color character is the better. In addition, the color filters may have excellent heat resistance, light resistance, and chemical resistance, so that they may not fade or be discolored under the ultraviolet rays, acid, or base conditions exposed during the etching process of a color resists. The color filters, which may be formed of photosensitive resin compositions, may be manufactured by coating three or more colors on a transparent substrate mainly by dyeing, electrodeposition, printing, pigment dispersion, or the like.

In addition to the LCD process, the photosensitive resin compositions may be used for next generation displays based on dye or pigment technologies. The conventional LCD process may be designed for securing durability in a high temperature process. The next generation displays may use a low temperature process in order to minimize thermal deformation loss due to material properties of thin films, and in addition, materials for organic light emitting diodes (OLED) may also use the low temperature process, and the demand for a low-temperature curable resin composition is increasing. A low-temperature curable resin composition could be insufficiently cured during the low-temperature curing and could exhibit unsatisfactory heat resistance and chemical resistance. An excessive hardening material could be used to form the thin films, and that could result in nonuniform surface characteristics and disadvantageous residues.

A photosensitive resin composition according to an embodiment may have a high curing rate at a low temperature and thus excellent solvent resistance and uniform coating characteristics. Some embodiments relate to a photosensitive resin composition capable of being cured at a low temperature and forming a color filter with excellent chemical resistance, e.g., a photosensitive resin composition having high reliability and patternability with pre-baking at about 100° C. and photocuring (i-line (365 nm) exposure).

Some color photoresists may be a negative photosensitive liquid material implemented in color patterns of red, green, and blue, and technology development has been made in the direction of gradually modifying the composition of the liquid material. Efforts have been made to improve color purity by modifying the type or content of the pigment dispersion, which is a coloring material that implements the color pattern, to improve patternability by modifying the composition of the binder resin or photopolymerization initiator, or to improve coating properties and color uniformity through the use of other additives such as leveling agents.

One or more embodiments may provide a photosensitive resin composition applied to a color filter process used in micro OLED display devices.

Herein, micro OLED refers to WOLED (White OLED) deposited on a silicon wafer. It may also be called OLEDoS (Organic Light Emitting Diode on Silicon). The micro OLED display devices refer to display devices to which the micro OLED is applied.

With the advent of the 4^{th} industrial revolution, as the metaverse market is rapidly growing, developing display devices increasing reality and visibility of AR, VR, and MR devices but minimizing dizziness has been considered. For this purpose, there are several candidate technologies such as LCoS (Liquid Crystal on Silicon), LEDoS (Light Emitting Diode on Silicon), OLEDoS (Organic Light Emitting Diode on Silicon), and the like. Among them, the OLEDoS technology may have advantages of a high contrast ratio, a fast response speed, and self-emission, which allows for a reduction in volume and weight of the devices to a relatively simple optical system and is being rapidly developed in many fields.

In OLEDoS, several m units of very smaller pixels (relative to other displays) may be formed in order to realize micro displays with a high resolution and that color filters may be formed through a low temperature process in order not to damage on lower OLED.

One or more embodiments may provide a photosensitive resin composition capable of being cured at a low temperature of about 100° C. or less, having excellent solvent resistance but almost no residues, and securing uniform exterior coating by limiting types of a binder resin in order to implement low-temperature curing and fine patterns and additionally, controlling a molecular weight of the binder resin and a solid content of the photosensitive resin composition. The photosensitive resin composition according to some embodiments may be applied due to these characteristics to display devices for VR (Virtual Reality), AR (Augmented Reality), and MR (Mixed Reality), which are next generation displays, e.g., micro OLED display devices.

Hereinafter, each component is described in detail.

### (A) Binder Resin

The binder resin may be an acrylic binder resin.

In an implementation, the acrylic binder resin may be an epoxy group-free acrylic binder resin that does not include an epoxy group.

The acrylic binder resin may include, e.g., a structural unit represented by one of Chemical Formula 1 or Chemical Formula 2, and may further include, e.g., at least two structural units represented by Chemical Formula 3 to Chemical Formula 5. In an implementation, the photosensitive resin composition according to some embodiments may have superior solvent resistance and coating appearance characteristics compared to other photosensitive resin compositions.

In an implementation, the binder resin may include structural units represented by Chemical Formula 1 and Chemical Formula 3 to Chemical Formula 5 (e.g., a structural unit represented by Chemical Formula 1, a structural unit represented by Chemical Formula 3, a structural unit represented by Chemical Formula 4, and a structural unit represented by Chemical Formula 5). In an implementation, R¹, R⁴, and R⁶ may each independently be, e.g., a substituted or unsubstituted C1 to C20 alkyl group, R², R⁵, and R¹ may each be, e.g., a hydrogen atom, and L¹ to L⁶ may each independently be, e.g., a substituted or unsubstituted C1 to C20 alkylene group. In an implementation, the photosensitive resin composition according to some embodiments may have higher reliability and patternability only through low-temperature curing and i-line exposure.

If the binder resin were to include a cardo binder resin, an epoxy binder resin, a silsesquioxane binder resin, or an epoxy-acrylic binder resin, curing could not occur well at low temperatures of about 100° C. or lower, and thus it could be difficult to improve reliability and patterning, and residue characteristics and coating uniformity may also deteriorate.

The photosensitive resin composition according to some embodiments may have excellent residue characteristics and coating uniformity even at low temperatures of about 100° C. or lower and with i-line exposure alone, and furthermore, color characteristics may also be improved because the structure within the binder resin, e.g., the acrylic binder resin, is controlled as described above.

In an implementation, the weight average molecular weight and double bond equivalent weight of the acrylic binder resin whose structure is controlled as described above may be further controlled, and the effects of improving residue characteristics, coating uniformity, and color properties may be further improved.

In an implementation, the binder resin may have a weight average molecular weight of, e.g., about 5,000 g/mol to about 8,000 g/mol.

In an implementation, the binder resin may have a double bond equivalent weight of, e.g., about 150 g/mol to about 500 g/mol.

In an implementation, the weight average molecular weight and/or double bond equivalent of the acrylic binder resin may be controlled as above, and the aforementioned improvement effects may be further doubled by low temperature of about 100° C. or lower and i-line exposure.

In an implementation, the photosensitive resin composition according to some embodiments may double the aforementioned effect by controlling the content of solids constituting the composition. In an implementation, the solid content of the photosensitive resin composition may be, e.g., about 12 wt % to about 24 wt % based on a total weight of the photosensitive resin composition.

In some other photosensitive resin compositions for color filters, the solid content may be greater than the above range. The photosensitive resin composition according to some embodiments may be applied to a micro OLED display device including a WOLED deposited on a silicon wafer rather than a glass substrate or polyimide as a light source, low-temperature curing may be essential, and therefore, controlling the solid content as above may be more advantageous in improving patternability. In an implementation, the solid content may be about 12 wt % to about 24 wt %, based on a total weight of the photosensitive resin composition, sufficient polymerization may occur with the photopolymerization initiator described later during exposure in the low-temperature pattern formation process, and even under low-temperature processes of about 100° C. or lower, patterns with excellent heat resistance, light resistance, and chemical resistance may be formed. Some other color filters for liquid crystal displays (LCDs) may use resist to form patterns of about 100 m, and the patterns may be too large to be used for micro OLED display devices. In an implementation, the type of binder resin, weight average molecular weight, and double bond equivalent, as well as the solid content constituting the photosensitive resin composition may be controlled, as described above, to implement fine patterns and enable low-temperature curing.

The binder resin may be included in an amount of about 5 wt % to about 20 wt %, e.g., about 5 wt % to about 15 wt %, or about 7 wt % to about 12 wt %, based on a total weight of the photosensitive resin composition. By including the binder resin within the above ranges, excellent sensitivity, developability, resolution, and linearity of the pattern may be obtained.

### (B) Colorant

The photosensitive resin composition according to some embodiments may include a colorant, e.g., a green pigment, a blue pigment, a red pigment, a violet pigment, a yellow pigment, or the like.

The red pigment may include, e.g., C.I. Red Pigment 254, C.I. Red Pigment 255, C.I. Red Pigment 264, C.I. Red Pigment 270, C.I. Red Pigment 272, C.I. Red Pigment 177, C.I. Red Pigment 89, or the like in the color index, which may be used alone or in a mixture of two or more.

The violet pigment may include, e.g., C.I. Violet Pigment 23 (V23), C.I. Violet Pigment 29, Dioxazine Violet, First Violet B, Methyl Violet Lake, Indanethrene Brilliant Violet, or the like in the color index, which may be used alone or in a mixture of two or more.

The green pigment may include, e.g., C.I. Green Pigment 7, C.I. Green Pigment 36, C.I. Green Pigment 58, C.I. Green Pigment 59 or the like in the color index, which may be used alone or in a mixture of two or more.

The blue pigment may include, e.g., copper phthalocyanine pigments such as C.I. Blue Pigment 15:6, C.I. Blue Pigment 15, C.I. Blue Pigment 15:1, C.I. Blue Pigment 15:2, C.I. Blue Pigment 15:3, C.I. Blue Pigment 15:4, C.I. Blue Pigment 15:5, C.I. Blue Pigment 15:6, C.I. Blue Pigment 16 or the like in the color index, which may be used alone or in a mixture of two or more.

The yellow pigment may include, e.g., an isoindoline pigment such as C.I. Yellow Pigment 185, C.I. Yellow Pigment 139, and the like, a quinophthalone pigment such as C.I. Yellow Pigment 138, a nickel complex pigment such as C.I. Yellow Pigment 150, or the like in the color index, which may be used alone or in a mixture of two or more.

The above pigments can be used alone or in a mixture of two or more.

The pigment may be pre-treated using a water-soluble inorganic salt and a wetting agent. In an implementation, the pigment may be pre-treated, and an average particle diameter of the pigment may become finer.

The pre-treatment may be performed by kneading the pigment with a water-soluble inorganic salt and a wetting agent and then, filtering and washing the kneaded pigment.

The kneading may be performed at a temperature of about 40° C. to about 100° C., and the filtering and washing may be performed by filtering the pigment after washing away an inorganic salt with water and the like.

Examples of the water-soluble inorganic salt may include sodium chloride, potassium chloride, and the like. The wetting agent may make the pigment to be uniformly mixed with the water-soluble inorganic salt uniformly and be pulverized. Examples of the wetting agent may include alkylene glycol monoalkyl ethers such as ethylene glycol monoethylether, propylene glycol monomethylether, diethylene glycol monomethylether, and the like, and alcohols such as ethanol, isopropanol, butanol, hexanol, cyclohexanol, ethylene glycol, diethylene glycol, polyethylene glycol, glycerine polyethylene glycol, and the like. These may be used alone or as a mixture of two or more.

The pigment after the kneading may have an average particle diameter ranging from about 5 nm to about 200 nm, e.g., about 5 nm to about 150 nm. Within the above ranges, stability in the pigment mill base (pigment dispersion) may be excellent, and pixel resolution may not be deteriorated.

The pigment may be used in the form of a pigment dispersion, such as a mill base, together with a dispersant and a solvent.

The dispersant may help the pigment to be uniformly dispersed in the dispersion, and each of non-ionic, anionic or cationic dispersants may be used. In an implementation, polyalkylene glycol or an ester thereof, polyoxy alkylene, a polyhydric alcohol ester alkylene oxide adduct, an alcohol alkylene oxide adduct, sulfonic acid ester, sulfonic acid salt, carboxylic acid ester, carboxylic acid salt, alkyl amide alkylene oxide adduct, an alkylamine, or the like may be used, and these may be used alone or in combination of two or more.

Commercially available examples of the dispersing agent may include DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK-166, DISPERBYK-170, DISPERBYK-171, DISPERBYK-182, DISPERBYK-2000, DISPERBYK-2001, and the like made by BYK Co., Ltd.; EFKA-47, EFKA-47EA, EFKA-48, EFKA-49, EFKA-100, EFKA-400, EFKA-450, and the like made by EFKA Chemicals Co.; Solsperse 5000, Solsperse 12000, Solsperse 13240, Solsperse 13940, Solsperse 17000, Solsperse 20000, Solsperse 24000GR, Solsperse 27000, Solsperse 28000, and the like made by Zeneka Co.; or PB711, or PB821 made by Ajinomoto Inc.

The dispersant may be included in an amount of about 0.1 wt % to about 15 wt %, based on a total weight of the photosensitive resin composition. By including the dispersant within the above range, the dispersibility of the composition may be excellent, and thus stability, developability, and patternability may be excellent when manufacturing a photosensitive resin layer.

In addition to the pigment, the dispersant, and the (dispersion) solvent, the pigment dispersion may further include a dispersion auxiliary agent, a dispersion resin, or the like. The solid pigment may be included in an amount of about 5 wt % to about 20 wt %, e.g., about 8 wt % to about 15 wt %, based on a total weight of the pigment dispersion.

The (dispersion) solvent of the pigment dispersion may include ethylene glycol acetate, ethyl cellosolve, propylene glycol methyl ether acetate, ethyl lactate, polyethylene glycol, cyclohexanone, propylene glycol methyl ether, or the like, e.g., propylene glycol methyl ether acetate.

As the dispersion resin, an acrylic resin including a carboxyl group may be used, which may help improve the stability of the pigment dispersion as well as the patternability of the pixel.

The colorant may include the pigment and may further include a dye, and in this case, the photosensitive resin composition according to some embodiments may be a hybrid composition. In an implementation, the dye may include a metal complex dye.

The metal complex dye may be a compound having maximum absorbance in the wavelength range of 200 nm to 650 nm. In an implementation, the compound may have absorbance in the above range in order to match the color coordinates to the combination of dyes, and the metal complex dye of all colors that dissolves in an organic solvent may be used.

In an implementation, the metal complex dye may be a green dye having maximum absorbance in a wavelength range of 530 nm to 680 nm, a yellow dye having maximum absorbance in a wavelength range of 200 nm to 400 nm, an orange dye having a maximum absorbance in a wavelength range of 300 nm to 500 nm, a red dye having maximum absorbance in a wavelength range of 500 nm to 650 nm, or a combination thereof.

The metal complex dye may be a direct dye, an acidic dye, a basic dye, an acidic mordant dye, a sulfide dye, a reduction dye, an azoic dye, a dispersion dye, a reactive dye, an oxidation dye, an oil-soluble dye, an azo dye, an anthraquinone dye, an indigoid dye, a carbonium ion dye, a phthalocyanine dye, a nitro dye, a quinoline dye, a cyanine dye, a polymethine dye, or a combination thereof.

The metal complex dye may include a metal ion of, e.g., Mg, Ni, Cu, Co, Zn, Cr, Pt, Pd, or Fe.

The metal complex dye may be a complex of, e.g., C.I. Solvent Dye such as C.I. Solvent Green 1, 3, 4, 5, 7, 28, 29, 32, 33, 34, 35, or the like; C.I. Acid Dye such as C.I. Acid Green 1, 3, 5, 6, 7, 8, 9, 11, 13, 14, 15, 16, 22, 25, 27, 28, 41, 50, 50:1, 58, 63, 65, 80, 104, 105, 106, 109, or the like; C.I. Direct Dye such as C.I. Direct Green 25, 27, 31, 32, 34, 37, 63, 65, 66, 67, 68, 69, 72, 77, 79, 82, or the like; C.I. Basic Dye such as C.I. Basic Green 1, or the like; C.I. Mordant Dye such as C.I. Mordant Green 1, 3, 4, 5, 10, 13, 15, 19, 21, 23, 26, 29, 31, 33, 34, 35, 41, 43, 53, or the like; C.I. Green pigments such as Pigment Green 7, 36, 58, or the like; Solvent Yellow 19, Solvent Yellow 21, Solvent Yellow 25, Solvent Yellow 79, Solvent Yellow 82, Solvent Yellow 88, Solvent Orange 45, Solvent Orange 54, Solvent Orange 62, Solvent Orange 99, Solvent Red 8, Solvent Red 32, Solvent Red 109, Solvent Red 112, Solvent Red 119, Solvent Red 124, Solvent Red 160, Solvent Red 132, or Solvent Red 218, and the metal ion.

The metal complex dye may have a solubility of greater than or equal to 5, e.g., 5 to 10, in a solvent used in the photosensitive resin composition according to some embodiments, as described below. The solubility may be obtained by an amount (g) of the dye dissolved in 100 g of the solvent. In an implementation, the solubility of the metal complex dye may be within the above ranges, compatibility with other components constituting the photosensitive resin composition according to some embodiments and coloring power may be secured, and precipitation of the dye may be prevented.

The solvent may include, e.g., propylene glycol monomethyl ether acetate (PGMEA), ethyl lactate (EL), ethylene glycol ethyl acetate (EGA), cyclohexanone, 3-methoxy-1-butanol, or a combination thereof.

The metal complex dye may be included in an amount of about 0.01 wt % to about 1 wt %, e.g., about 0.01 wt % to about 0.5 wt %, based on a total weight of the photosensitive resin composition. By including the metal complex dye within the above ranges, high luminance and contrast ratio may be exhibited in a desired color coordinate.

In an implementation, the dye and the pigment may be mixed and used in a weight ratio of about 0.1:99.9 to about 99.9:0.1, e.g., about 1:9 to about 9:1. By mixing within the above weight ratio ranges, chemical resistance and maximum absorption wavelength may be controlled within an appropriate range, and high luminance and contrast ratio may be exhibited in a desired color coordinate.

The colorant may be included in an amount of about 70 wt % to about 90 wt %, e.g., about 70 wt % to about 85 wt %, or about 75 wt % to about 80 wt %, based on a total weight of the photosensitive resin composition. By including the colorant in a very high content as described above, the coloring effect and developability are excellent in the micro OLED display device, making it easy to secure high color gamut and viewing angle characteristics.

### (C) Polymerizable Monomer

The polymerizable monomer in the photosensitive resin composition according to some embodiments may include, e.g., a compound including three or more functional groups. In an implementation, the functional group may include, e.g., a (meth)acrylate group, an epoxy group, or the like.

The photosensitive resin composition according to some embodiments has been developed for use in micro OLED display devices, and a low-temperature curing process may be performed. In the case of a low-temperature curing pattern process, contribution of thermal curing may be reduced and the influence of photocuring may increase. Accordingly, maximizing photocuring efficiency may be advantageous for securing excellent patternability under low-temperature curing. In an implementation, photocuring efficiency may be maximized by using a compound having at least three functional groups in the monomer as a polymerizable monomer. In an implementation, the photocuring efficiency may be greatly affected by a weight average molecular weight of the polymerizable monomer and the number of functional groups. The smaller the weight average molecular weight of the polymerizable monomer and the greater the number of functional groups in the polymerizable monomer, the higher the photocuring efficiency. In an implementation, the compound having at least three functional groups in the monomer may have a small weight average molecular weight and a large number of functional groups, so that they may be advantageous for maximizing photocuring efficiency.

In an implementation, the polymerizable monomer may be a mixture of two (or more) types of compounds. In an implementation, each compound of the two types of compounds may independently be a compound including three or more functional groups. In an implementation, the polymerizable monomer may be a mixture of a first polymerizable monomer that includes 3 to 5 functional groups and a second polymerizable monomer that includes 6 or more functional groups. In an implementation, the polymerizable monomer may include the above mixed composition, and photocuring efficiency may be maximized while maintaining the aforementioned color characteristics, making it easy to form a low-temperature curing pattern.

In an implementation, the first polymerizable monomer may be included in a smaller amount than the second polymerizable monomer. Within such a weight ratio, low-temperature curing patternability may be ideal.

In an implementation, the polymerizable compound including three or four functional groups may be represented by, e.g., Chemical Formula X.

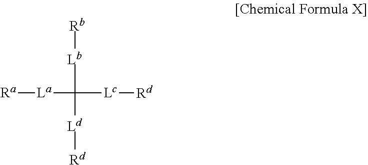

In Chemical Formula X, L^{a} to L^{d} may each independently be, e.g., a substituted or unsubstituted C1 to C20 alkylene group, a substituted or unsubstituted C1 to C20 oxyalkylene group, or a combination thereof.

R^{a} to R^{d} may each independently be, e.g., hydrogen, a hydroxy group, epoxy group or a substituted or unsubstituted (meth)acrylate group. In an implementation, at least three of R¹ to R⁴ may be an epoxy group or a substituted or unsubstituted (meth)acrylate group.

In an implementation, the compound including 5 to 6 functional groups may include, e.g., pentaerythritol hexa(meth)acrylate, dipentaerythritol penta(meth)acrylate, dipentaerythritol hexa(meth)acrylate, or a combination thereof.

The polymerizable monomer may be used after being treated with an acid anhydride to help provide better developability.

The polymerizable monomer may be included in an amount of about 1 wt % to about 10 wt %, e.g., about 1 wt % to about 5 wt %, based on the total weight of the photosensitive resin composition. By including the polymerizable monomer within the above ranges, curing may occur sufficiently during exposure to light in a low-temperature pattern formation process, resulting in excellent reliability, excellent heat resistance, light resistance, and chemical resistance of the pattern, and excellent resolution and adhesion.

### (D) Polymerization Initiator

The photosensitive resin composition according to some embodiments may include a polymerization initiator. In an implementation, the polymerization initiator may be included in an amount of about 0.1 wt % to about 5 wt %, e.g., about 1 wt % to about 3 wt %, based on a total weight of the photosensitive resin composition. By including the polymerization initiator within the above ranges of amounts, an optimal pattern may be formed in a low-temperature curing process along with the composition of the aforementioned polymerizable monomer, binder resin, and colorant. If the amount of the polymerization initiator were to be outside the above amount ranges in the composition of the aforementioned polymerizable monomer, binder resin, and colorant, patternability could be greatly reduced during the low-temperature curing process.

The polymerization initiator may include, e.g., an acetophenone compound, a benzophenone compound, a thioxanthone compound, a benzoin compound, a triazine compound, an oxime compound, or a combination thereof.

Examples of the acetophenone compound may include 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloroacetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone compound may include benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone compound may include thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin compound may include benzoin, benzoin methyl ether, benzoin ethyl ether, benzoin isopropyl ether, benzoin isobutyl ether, benzyl dimethyl ketal, and the like.

Examples of the triazine compound may include 2,4,6-trichloro-s-triazine, 2-phenyl 4,6-bis(trichloromethyl)-s-triazine, 2-(3′, 4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloromethyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime compound may include an O-acyloxime-based compound, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Specific examples of the o-acyloxime-based compound may be 1,2-octanedione, 2-dimethylamino-2-(4-methylbenzyl)-1-(4-morpholin-4-yl-phenyl)-butan-1-one, 1-(4-phenylsulfanyl phenyl)-butane-1,2-dione2-oxime-O-benzoate, 1-(4-phenylsulfanyl phenyl)-octane-1,2-dione2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

In an implementation, in addition to the above compounds, the polymerization initiator may also be used together with, e.g., a carbazole compound, a diketone compound, a sulfonium borate compound, a diazo compound, an imidazole compound, a biimidazole compound, or the like.

### (E) Solvent

The solvent may be a material that has compatibility with the pigment dispersion including the colorant, the binder resin, the polymerizable monomer, and the polymerization initiator, but does not react therewith.

Examples of the solvent may include alcohols such as methanol, ethanol, and the like; ethers such as dichloroethylether, n-butylether, diisoamylether, methylphenylether, tetrahydrofuran, and the like; glycolethers such as ethylene glycolmonomethylether, ethylene glycolmonoethylether, ethylene glycoldimethylether, and the like; cellosolveacetates such as methylcellosolveacetate, ethylcellosolveacetate, diethylcellosolveacetate, and the like; carbitols such as methylethylcarbitol, diethylcarbitol, diethylene glycolmonomethylether, diethylene glycolmonoethylether, diethylene glycoldimethylether, diethylene glycolethylmethylether, diethylene glycoldiethylether, and the like; propylene glycolalkyletheracetates such as propylene glycolmethyletheracetate, propylene glycolpropyletheracetate, and the like; aromatic hydrocarbons such as toluene, xylene, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, oxy butyl acetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxypropionic acid alkyl esters such as 3-oxymethyl propionate, 3-oxyethyl propionate, and the like; 3-alkoxypropionic acid alkyl esters such as 3-methoxymethyl propionate, 3-methoxyethyl propionate, 3-ethoxyethyl propionate, 3-ethoxymethyl propionate, and the like; 2-oxypropionic acid alkyl esters such as 2-oxymethyl propionate, 2-oxyethyl propionate, 2-oxypropyl propionate, and the like; 2-alkoxypropionic acid alkyl esters such as 2-methoxymethyl propionate, 2-methoxyethyl propionate, 2-ethoxyethyl propionate, 2-ethoxymethyl propionate, and the like; 2-oxy-2-methylpropionic acid esters such as 2-oxy-2-methylmethyl propionate, 2-oxy-2-methylethyl propionate, and the like, monooxy monocarboxylic acid alkyl esters of 2-alkoxy-2-methyl alkyl propionates such as 2-methoxy-2-methylmethyl propionate, 2-ethoxy-2-methylethyl propionate, and the like; esters such as 2-hydroxyethyl propionate, 2-hydroxy-2-methylethyl propionate, hydroxy ethyl acetate, 2-hydroxy-3-methyl methyl butanoate, and the like; ketonate esters such as ethyl pyruvate, and the like. In an implementation, a high boiling point solvent such as N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and the like may be also used.

Considering miscibility and reactivity, glycolethers such as ethylene glycolmonoethylether, ethylene glycoldimethylether, ethylene glycoldiethylether, diethylene glycolethylmethylether, and the like; ethylene glycolalkylether acetates such as ethyl cellosolveacetate, and the like; esters such as 2-hydroxyethyl propionate, and the like; carbitols such as diethylene glycolmonomethylether, and the like; propylene glycolalkyletheracetates such as propylene glycolmonomethyl ether acetate, propylene glycolpropyletheracetate, and the like may be used.

The solvent may be included in a balance amount, e.g., about 0.1 wt % to about 20 wt %, about 1 wt % to about 20 wt %, or about 3 wt % to about 18 wt %, based on a total weight of the photosensitive resin composition. By including the solvent within the above ranges, the photosensitive resin composition may have an appropriate viscosity and thus processability is improved during a production of a photosensitive resin layer.

### (F) Other Additives

In an implementation, the photosensitive resin composition may further include an additive, e.g., malonic acid, 3-amino-1,2-propanediol, a silane coupling agent, a leveling agent, a surfactant, an antioxidant, or a combination thereof.

The silane coupling agent may have a reactive substituent such as a vinyl group, a carboxyl group, a methacryloxy group, an isocyanate group, or an epoxy group to help improve adhesion to the substrate.

Examples of the silane coupling agent may include trimethoxysilylbenzoic acid, γ-methacryloxypropyltrimethoxysilane, vinyltriacetoxysilane, vinyltrimethoxysilane, γ-isocyanatepropyltriethoxysilane, γ-glycidoxypropyltrimethoxysilane, 3-(3,4-epoxycyclohexyl)ethyltrimethoxysilane, and the like. These may be used alone or in a mixture of two or more.

The silane coupling agent may be included in an amount of about 0.01 parts by weight to about 10 parts by weight, based on 100 parts by weight of the photosensitive resin composition. By including the silane coupling agent within the above range, adhesion, storage capability, and the like may be improved.

In an implementation, the photosensitive resin composition may further include a surfactant, e.g., a fluorine surfactant or a silicone surfactant, to help improve coating properties and prevent defect formation.

Examples of the fluorine surfactant may include a commercial fluorine surfactant such as BM-1000®, BM-1100®, and the like of BM Chemie Inc.; MEGAFACE F 142D®, MEGAFACE F 172®, MEGAFACE F 173®, MEGAFACE F 183®, MEGAFACE F 554®, and the like of Dainippon Ink Kagaku Kogyo Co., Ltd.; FULORAD FC-135®, FULORAD FC-170C®, FULORAD FC-430®, FULORAD FC-431®, and the like of SUMITOMO 3M Co., Ltd.; SURFLON S-112®, SURFLON S-113®, SURFLON S-131®, SURFLON S-141®, SURFLON S-145®, and the like ofAsahi Glass Co., Ltd.; SH-28PA®, SH-190®, SH-193®, SZ-6032®, SF-8428®, and the like of Toray Silicone Co., Ltd.

The silicone surfactant may include a commercial silicone surfactant such as BYK-307, BYK-333, BYK-361N, BYK-051, BYK-052, BYK-053, BYK-067A, BYK-077, BYK-301, BYK-322, BYK-325, or the like of BYK Chem.

The surfactant may be included in an amount of about 0.001 parts by weight to about 5 parts by weight, based on 100 parts by weight of the photosensitive resin composition. By including the surfactant within this range, coating uniformity may be secured, a stain may not be produced, and wetting on an IZO substrate or a glass substrate is improved.

The antioxidant may include a hydroquinone compound, a catechol compound, or a combination thereof. In an implementation, the photosensitive resin composition according to some embodiments may further include the hydroquinone compound, the catechol compound, or a combination thereof, and room temperature crosslinking may be prevented during exposure to light after coating the photosensitive resin composition.

In an implementation, the hydroquinone compound, catechol compound, or combination thereof may include hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis(1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum, or a combination thereof.

The hydroquinone compound, catechol compound, or combination thereof may be used in the form of a dispersion, and the antioxidant in the form of the dispersion may be included in an amount of about 0.001 wt % to about 3 wt %, e.g., about 0.01 wt % to about 1 wt %, based on a total weight of the photosensitive resin composition. By including the antioxidant within the above ranges, it is possible to address issues with respect to aging at room temperature and to help prevent deterioration of sensitivity and surface peeling.

In an implementation, the photosensitive resin composition may include other additives, e.g., a stabilizer or the like, in a suitable amount, unless they deteriorate properties of the photosensitive resin composition.

The photosensitive resin composition according to some embodiments may be either positive or negative. In an implementation, the composition may be a negative composition to completely remove residues in regions where a pattern is exposed after exposing and developing the composition having light blocking properties.

Some embodiments may provide a photosensitive resin layer manufactured by low-temperature curing, exposure, and development of the aforementioned photosensitive resin composition. Compared to some LCD processes, the difference may be that the post-curing (post-baking) process is unnecessary.

A method of manufacturing the photosensitive resin layer may be as follows.

### (1) Coating and Film Formation (Low-Temperature Curing)

The photosensitive resin composition may be coated to have a desired thickness on a substrate such as a glass substrate or ITO substrate, or the like which may undergo a pretreatment, using a spin or slit coating method, a roll coating method, a screen-printing method, an applicator method, or the like, and may be heated at about 100° C. or lower, e.g., about 85° C., for about 1 minute to 10 minutes to remove a solvent and thereby to form a photosensitive resin layer. Through this step, it may be possible to improve image quality or the like.

### (2) Exposure

After disposing a mask to form a desired pattern on the obtained photosensitive resin layer, exposure may be performed by irradiating an actinic ray of i-line. As a light source used for irradiation, a low-pressure mercury lamp, a high-pressure mercury lamp, an ultra-high pressure mercury lamp, a metal halide lamp, an argon gas laser, or the like may be used. In an implementation, an X-ray, an electron beam, or the like may be used.

The exposure process may use, e.g., a light dose of 500 mJ/cm² or less (with a 365 nm sensor), in the event that a high-pressure mercury lamp is used. In an implementation, the light dose may vary depending on types of each component, a combination ratio thereof, and a dry film thickness. In an implementation, the exposure amount may exceed 500 mJ/cm² (by 365 nm sensor). Through this step, fine adjustment of the pixel size is possible, enabling high-resolution implementation.

### (3) Development

In the development method, following the exposure step, an alkaline aqueous solution may be used as a developer to dissolve and remove unnecessary parts, leaving only the exposed parts remaining to form a pattern. Through this step, a profile may be formed to realize high resolution, and color uniformity can be secured to improve clarity.

Some embodiments provide a display device including the photosensitive resin layer.

The display device may be a micro organic light emitting diode (OLED) display device.

The micro organic light emitting diode (OLED) display device may include an OLED substrate deposited on a silicon wafer and a color filter layer stacked on the OLED substrate and converting white light generated from the OLED substrate into a plurality of color lights. In an implementation, the color filter layer may include a red color filter, a green color filter, and a blue color filter.

In an implementation, the micro organic light emitting diode (OLED) display device may include an OLED substrate deposited on a silicon wafer, an inorganic layer stacked on the OLED substrate, an adhesive protection layer stacked on the inorganic layer, and a color filter layer stacked on the adhesive protection layer and converting white light generated from the OLED substrate into a plurality of color lights. In an implementation, the color filter layer may include a red color filter, a green color filter, and a blue color filter.

In an implementation, the photosensitive resin composition according to some embodiments may be a green photosensitive resin composition, and the green color filter in the micro OLED display device may be a low-temperature cured layer of the green photosensitive resin composition.

Some OLED substrates in which OLEDs are deposited on a glass or polyimide substrate have been used. The micro OLED display device according to some embodiments may be more advantageous in implementing a micro display because the OLED may be deposited on a silicon wafer. These micro displays are in the spotlight as next-generation displays, and the micro displays are expected to be applied to devices such as MR.

In an implementation, the micro OLED display device may further include a micro lens array. The micro lens array may be on the adhesive protection layer and may surround the color filter layer.

The micro OLED display device with the above structure may be driven on a pixel basis by depositing WOLED on a highly integrated silicon wafer, and it may be easy to control the transmission wavelength through a color filter layer patterned with a resolution of less than or equal to about 3 μm, enabling high color reproduction and securing high resolution.

In an implementation, the adhesive protection layer may have a thickness of less than or equal to about 1 μm, and the above effect may be further maximized.

In an implementation, the color filter layer may have a thickness of about 1.1 μm to about 1.6 μm.

Maintaining the thickness of the color filter layer within the above ranges may help ensure that it is more advantageous to implement a micro OLED display device.

In an implementation, the inorganic layer may have a thickness of less than or equal to about 2 μm. Even with WOLED, light may not always diffuse in the direction perpendicular to the OLED substrate, so that color mixing of red, green, and blue could inevitably occur. An inorganic layer could be deposited on the OLED substrate in an effort to help prevent such color mixing. The color mixing may not be completely prevented even by depositing an inorganic layer. In an implementation, subtle light leakage phenomenon may be prevented by thinning the inorganic layer, e.g., by controlling the thickness of the inorganic layer to less than or equal to about 2 μm.

In an implementation, the photosensitive resin composition according to some embodiments may allow the production of a cured layer only through low-temperature (100° C.) curing during prebaking and i-line photocuring, as described above, and there may be a huge difference in resolution that may be implemented compared to other display devices.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### (Preparation of Photosensitive Resin Composition)

### Examples 1 to 10 and Comparative Examples 1 and 2

With the compositions shown in Tables 1 and 2, a polymerization initiator was dissolved in a solvent and stirred at ambient temperature for 2 hours. Here, the binder resin and the polymerizable monomer were added, and stirred at ambient temperature for 1 hour. After adding other additives and colorants thereto, the solutions were stirred at ambient temperature for 1 hour, and then the entire solutions were stirred for 2 hours. The solutions were filtered three times to remove impurities to prepare each photosensitive resin composition.

TABLE 1
(unit: wt %)

| | | | | | | | | | | | | Comp. | Comp. |
|---|---|---|---|---|---|---|---|---|---|---|---|---|---|
| | | Ex. 1 | Ex. 2 | Ex. 3 | Ex. 4 | Ex. 5 | Ex. 6 | Ex. 7 | Ex. 8 | Ex. 9 | Ex. 10 | Ex. 1 | Ex. 2 |
| (A) binder resin | (A-1) | 9.53 | — | 9.53 | 9.53 | — | — | — | 9.53 | 9.53 | 9.53 | — | — |
| | (A-2) | — | 9.53 | — | — | — | — | — | — | — | — | — | — |
| | (A-3) | — | — | — | — | 9.53 | — | — | — | — | — | — | — |
| | (A-4) | — | — | — | — | — | 9.53 | — | — | — | — | — | — |
| | (A-5) | — | — | — | — | — | — | 9.53 | — | — | — | — | — |
| | (A-6) | — | — | — | — | — | — | — | — | — | — | 9.53 | — |
| | (A-7) | — | — | — | — | — | — | — | — | — | — | — | 9.53 |
| (B) colorant | | 79.35 | 79.35 | 69.24 | 83.88 | 79.35 | 79.35 | 79.35 | 67.91 | 84.82 | 79.35 | 79.35 | 79.35 |
| (C) polymerizable | (C-1) | 2.1 | 2.1 | 2.1 | 2.1 | 2.1 | 2.1 | 2.1 | 2.1 | 2.1 | 0.9 | 2.1 | 2.1 |
| monomer | (C-2) | 0.9 | 0.9 | 0.9 | 0.9 | 0.9 | 0.9 | 0.9 | 0.9 | 0.9 | 2.1 | 0.9 | 0.9 |
| (D) polymerization initiator | | 1.67 | 1.67 | 1.67 | 1.67 | 1.67 | 1.67 | 1.67 | 1.67 | 1.67 | 1.67 | 1.67 | 1.67 |
| (E) solvent | | 5.867 | 5.867 | 15.977 | 1.337 | 5.867 | 5.867 | 5.867 | 17.307 | 0.397 | 5.867 | 5.867 | 5.867 |
| (F) other additive | (F-1) | 0.2 | 0.2 | 0.2 | 0.2 | 0.2 | 0.2 | 0.2 | 0.2 | 0.2 | 0.2 | 0.2 | 0.2 |
| | (F-2) | 0.254 | 0.254 | 0.254 | 0.254 | 0.254 | 0.254 | 0.254 | 0.254 | 0.254 | 0.254 | 0.254 | 0.254 |
| | (F-3) | 0.13 | 0.13 | 0.13 | 0.13 | 0.13 | 0.13 | 0.13 | 0.13 | 0.13 | 0.13 | 0.13 | 0.13 |

| | | | | | | | | | | | | |
|---|---|---|---|---|---|---|---|---|---|---|---|---|
| solid content | 18 | 18 | 12 | 24 | 18 | 18 | 18 | 11 | 25 | 18 | 18 | 18 |

### (A) Binder Resin

(A-1) Acrylic binder resin including structural units represented by Chemical Formula A (Showa Denko) (8,000 g/mol)

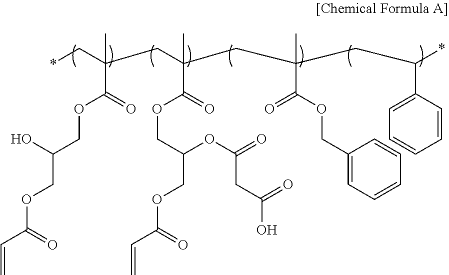

(A-2) Acrylic binder resin including structural units represented by Chemical Formula A (Showa Denko) (5,000 g/mol)

(A-3) Acrylic binder resin including structural units represented by Chemical Formula B (Showa Denko) (5,000 g/mol)

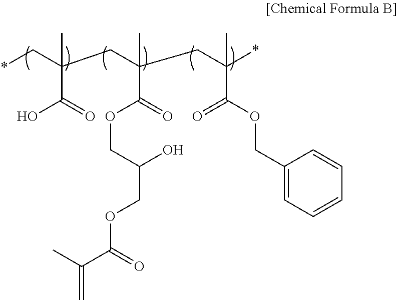

(A-4) Acrylic binder resin including structural units represented by Chemical Formula A (Showa Denko) (4,000 g/mol)

(A-5) Acrylic binder resin including structural units represented by Chemical Formula A (Showa Denko) (9,000 g/mol)

(A-6) Epoxy binder resin (EHPE3150, Daicel Chemical Industry Co., Ltd.)

(A-7) Silsesquioxane binder resin (EHPE3150, Daicel Chemical Industry Co., Ltd.)

### (B) Colorant

Pigment dispersion (Sanyo, BA6136)

### (C) Polymerizable Monomer

(C-1) dipentaerythritolhexa(meth)acrylate (DPHA, Nippon Kayaku Co. Ltd.)

(C-2) pentaerythritol triacrylate (PE-3A, Gongyoungsa Co., Ltd.)

### (D) Polymerization Initiator

Oxime initiator (SPI-03, Samyang Corp.)

### (E) Solvent

Propylene glycol monomethyl ether acetate (PGMEA, Daicel Co., Ltd.)

(F) Other additives

(F-1) Leveling agent (F-554, DIC Co., Ltd.)

(F-2) Silane coupling agent (KBM503, ShinEtsu)

(F-3) Antioxidant (2-Methylhydroquinone, JHChem)

### Evaluation

Each of the photosensitive compositions according to Examples 1 to 10 and Comparative Examples 1 and 2 was coated on an 8-inch silicon wafer at ab rpm capable of reaching a predetermined thickness (1.5 m) for each sample by using a K-spin 8 equipment (Track) (SEMES). Subsequently, the coated wafers were baked at 100° C. on a hot plate of the Track equipment for 3 minutes and then, exposed for forming patterns by adjusting an exposure dose (exposure condition=dose: 800 ms/focus: −0.3) with an i-line stepper made by Nikon Inc. In the exposure process, after measuring a thickness by using KLA_Tenscor, the exposed wafer was developed to reveal the patterns. Herein, the development was performed by using an EHD-100S developing solution (TMAH). The patterns of the patterned substrate completed with the development was confirmed to be 96 μm negative patterns by using CD-SEM made by Hitachi, Ltd. and checked with respect to sensitivity and residues, and using an optical microscope made by Olympus Corp was used to check large area coating uniformity. The coating uniformity was observed with naked eyes, wherein if excellent, o was given, if inferior, Δ was given, and if too inferior to be commercialized, X was given.

In addition, the patterned substrate was checked with respect to additional color changes by dipping (5 min) it in a TMAH (2.38%) developer BASF Corp. Colors were measured by using a fine pattern chromaticity meter (LCF).

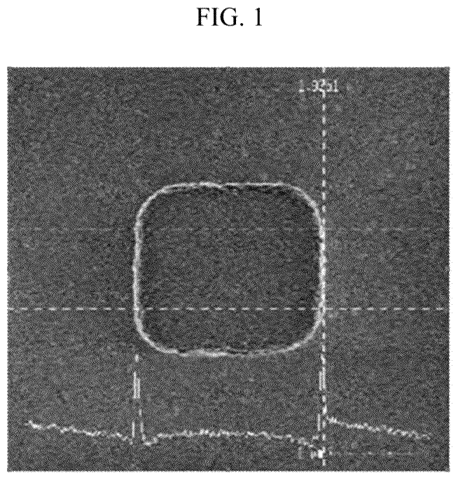

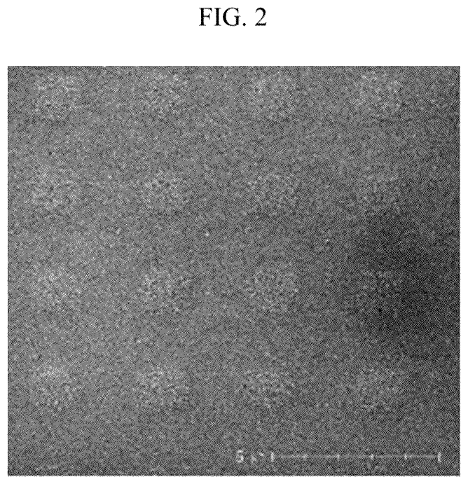

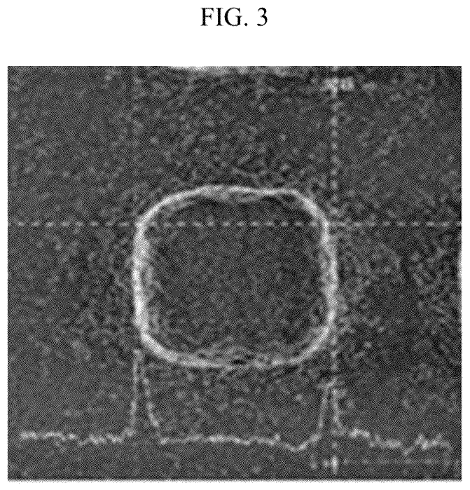

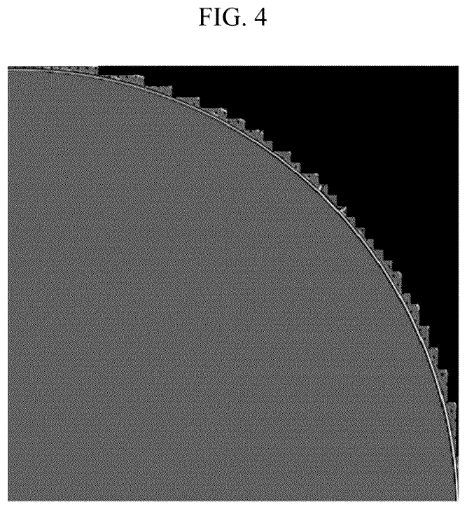

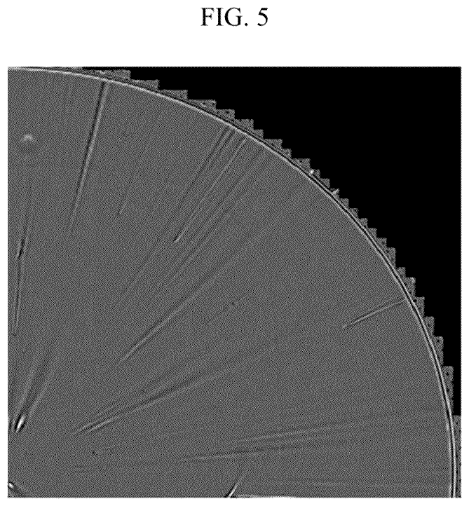

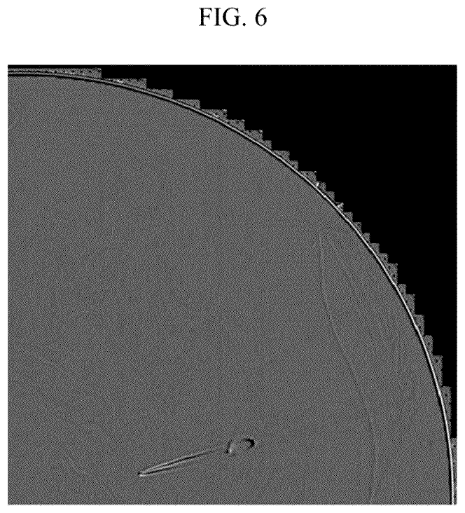

The evaluation results are shown in Table 2 and FIGS. 1 to 6.

TABLE 2

| | | | | | | | | | | | Comp. | Comp. |
|---|---|---|---|---|---|---|---|---|---|---|---|---|
| | Ex. 1 | Ex. 2 | Ex. 3 | Ex. 4 | Ex. 5 | Ex. 6 | Ex. 7 | Ex. 8 | Ex. 9 | Ex. 10 | Ex. 1 | Ex. 2 |
| Residue (CD- | ◯ | ◯ | ◯ | ◯ | Δ | Δ | Δ | Δ | Δ | Δ | X | X |
| SEM) | | | | | | | | | | | | |
| Coating | ◯ | ◯ | ◯ | ◯ | Δ | Δ | Δ | ◯ | ◯ | Δ | X | X |
| Uniformity | | | | | | | | | | | | |
| Del (E*) | 0.74 | 0.73 | 0.78 | 0.75 | 0.84 | 0.85 | 0.83 | 0.86 | 0.89 | 0.87 | 0.38 | 0.95 |

### Evaluation Criteria of Residue Characteristics

o: Residues around the pattern were not seen on an optical microscope.
Δ: Some residues around the pattern were seen on an optical microscope, but it was not severe.
X: Many residues around the pattern were seen on the optical microscope.

Referring to Table 2 and FIGS. 1 to 6, the photosensitive resin compositions according to the Examples implemented fine patterns despite the low-temperature curing and exhibited excellent residue characteristics, coating uniformity, and color characteristics and were suitably used for micro OLED display devices.

By way of summation and review, in the micro OLED display panels having 10 times smaller pixels than general OLED display panels, red (R)/green (G)/blue (B) light emitting layers could be difficult to from by using FMM (Fine Metal Mask) technology. In other words, if the liquid crystal displays were to be applied to devices for VR, AR, and the like, the color filters could have too large a pattern size to increase resolution.

Accordingly, OLEDos (OLED on Silicon) technology may achieve high resolution of about 4,000 ppi or more. The corresponding technology may use OLED deposited on a silicon wafer as a backlight to pattern color filters thereon. Some color filters used for liquid crystal displays may be formed by mounting about 100 m patterns on a glass and curing it through an exposure process and a post-baking process at a high temperature of about 230° C. or more, the color filters mounted on OLEDos may not go through the high temperature process due to OLED and must be cured at a low temperature, and in addition, micro-patterning is important in order to increase resolution. The VR and AR devices may be small in size, and the micro-patterning may be used to achieve desired resolution.

The low-temperature (about 100° C. or lower) curing may result in the color filters made of other materials having weak adhesion and generating residues.

One or more embodiments may provide a photosensitive resin composition that is sufficiently cured even at low temperatures to have excellent solvent resistance and coating appearance characteristics, and further has excellent color characteristics, thus having high reliability and patternability.

The photosensitive resin composition according to some embodiments can be cured at a low temperature of about 100° C. or lower, can secure high resolution through the implementation of fine patterns, and has excellent spectral characteristics, making it possible to secure a wide color gamut. In an implementation, it may have excellent solvent resistance even with only temperature and photocuring (i-line exposure) after pre-baking of about 100° C. or lower, may have excellent residue characteristics, and may have excellent coating appearance characteristics, making it suitable for micro OLED display devices.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photosensitive resin composition, comprising:
a binder resin;
a colorant;
a polymerizable monomer;
a polymerization initiator; and
a solvent
wherein:
the binder resin includes:
at least one structural unit represented by Chemical Formula 1 or Chemical Formula 2, and
at least two structural units represented by Chemical Formula 3 to Chemical Formula 5: 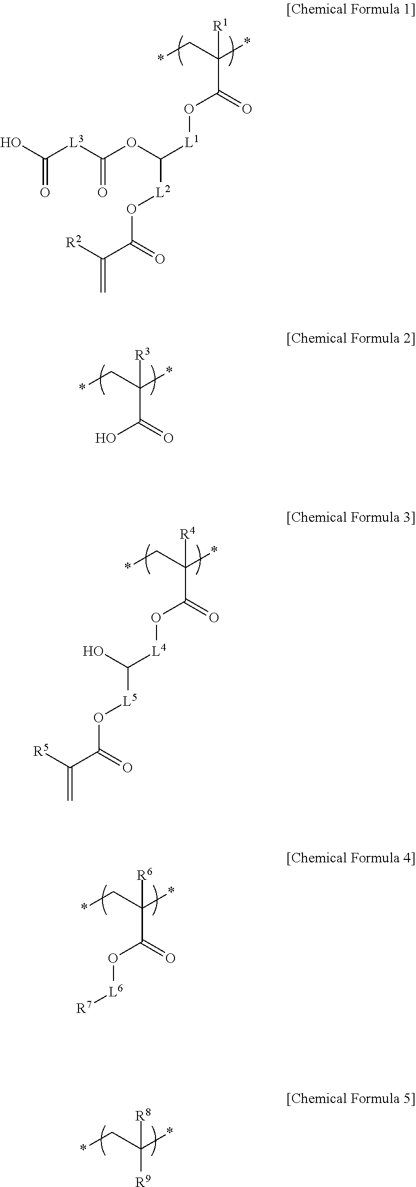
in Chemical Formula 1 to Chemical Formula 5,
R¹ to R⁶ and R⁸ are each independently a hydrogen atom or a substituted or unsubstituted C1 to C20 alkyl group,
R⁷ and R⁹ are each independently a substituted or unsubstituted C6 to C20 aryl group, and
L¹ to L⁶ are each independently a single bond or a substituted or unsubstituted C1 to C20 alkylene group.

2. The photosensitive resin composition as claimed in claim 1, wherein the binder resin includes:
a structural unit represented by Chemical Formula 1,
a structural unit represented by Chemical Formula 3,
a structural unit represented by Chemical Formula 4, and
a structural unit represented by Chemical Formula 5.

3. The photosensitive resin composition as claimed in claim 2, wherein
in Chemical Formula 1 and Chemical Formula 3 to Chemical Formula 5,
R¹, R⁴, and R⁶ are each independently a substituted or unsubstituted C1 to C20 alkyl group,
R², R⁵, and R⁸ are each a hydrogen atom, and
L¹ to L⁶ are each independently a substituted or unsubstituted C1 to C20 alkylene group.

4. The photosensitive resin composition as claimed in claim 1, wherein the binder resin has a weight average molecular weight of about 5,000 g/mol to about 8,000 g/mol.

5. The photosensitive resin composition as claimed in claim 1, wherein the binder resin has a double bond equivalent weight of about 150 g/mol to about 500 g/mol.

6. The photosensitive resin composition as claimed in claim 1, wherein the photosensitive resin composition includes solids in an amount of about 12 wt % to about 24 wt %, based on a total weight of the photosensitive resin composition.

7. The photosensitive resin composition as claimed in claim 1, wherein the polymerizable monomer includes a compound that includes three or more functional groups.

8. The photosensitive resin composition as claimed in claim 7, wherein:
the polymerizable monomer is a mixture of two types of compounds, and
each compound of the two types of compounds independently includes three or more functional groups.

9. The photosensitive resin composition as claimed in claim 8, wherein:
the two types of compounds include:
a first polymerizable monomer including 3 to 5 functional groups, and
a second polymerizable monomer including 6 or more functional groups, and
the first polymerizable monomer is included in an amount that is less than an amount of the second polymerizable monomer.

10. The photosensitive resin composition as claimed in claim 1, wherein the photosensitive resin composition includes, based on a total weight of the photosensitive resin composition,
about 5 wt % to about 20 wt % of the binder resin;
about 70 wt % to about 90 wt % of the colorant;
about 1 wt % to about 10 wt % of the polymerizable monomer;
about 0.1 wt % to about 5 wt % of the polymerization initiator; and
the solvent.

11. The photosensitive resin composition as claimed in claim 1, further comprising an antioxidant.

12. The photosensitive resin composition as claimed in claim 11, wherein the antioxidant is included in an amount of about 0.01 wt % to about 1 wt %, based on a total weight of the photosensitive resin composition.

13. The photosensitive resin composition as claimed in claim 1, further comprising malonic acid, 3-amino-1,2-propanediol, a silane coupling agent, a leveling agent, a surfactant, or a combination thereof.

14. A photosensitive resin layer manufactured using the photosensitive resin composition as claimed in claim 1.

15. A display device comprising the photosensitive resin layer as claimed in claim 14.

16. The display device as claimed in claim 15, wherein:
the display device is a micro OLED display device including an OLED substrate deposited on a silicon wafer and a color filter layer stacked on the OLED substrate and converting white light generated from the OLED substrate into a plurality of color lights, and
the color filter layer includes a red color filter, a green color filter, and a blue color filter.

17. A method of manufacturing a photosensitive resin layer, the method comprising:
coating the photosensitive resin composition as claimed in claim 1;
prebaking at a temperature of about 100° C. or lower after the coating;
exposing to i-line after the prebaking, and
developing.
